(19) United States
(12) Patent Application Publication
(10) Pub. No.: US 2012/0319705 A1
(43) Pub. Date: Dec. 20, 2012

(54) HYBRID THREE-DIMENSIONAL SENSOR ARRAY, IN PARTICULAR FOR MEASURING ELECTROGENIC CELL ASSEMBLIES, AND THE MEASURING ASSEMBLY

(75) Inventors: Andreas Schober, Furth (DE); Jörg Hampl, Erfurt (DE); Uta Fernekorn, Erfurt (DE); Peter Husar, Ilmenau (DE); Michael Fischer, Uhlstadt-Kirchhasel (DE); Daniel Laqua, Ilmenau (DE); Katharina Lilienthal, Ilmenau (DE)

(73) Assignee: TECHNISCHE UNIVERSITAT ILMENAU, Ilmenau (DE)

(21) Appl. No.: 13/581,060

(22) PCT Filed: Feb. 23, 2011
(86) PCT No.: PCT/EP2011/052638

§ 371 Date: Aug. 24, 2012

(30) Foreign Application Priority Data
Feb. 26, 2010 (DE) 10 2010 000 565.7

(51) Int. Cl. G01R 19/00; G01R 27/26

(52) U.S. Cl. 324/658; 324/76.11

(57) ABSTRACT

The invention relates to a hybrid three-dimensional sensor array, in particular for measuring biological cell assemblies. The sensor array has a plurality of microstructured sensor plates, each having one carrier section on which a plurality of sensor needles are arranged in a comb-like manner, which carry a plurality of electrode surfaces. Furthermore, a plurality of spacer elements are provided, which are fastened between the sensor plates so that both the carrier sections and the sensor needles of adjacent sensor plates are at a distance from each other. The invention further relates to a measuring assembly for measuring electrical activities of biological cell assemblies using such a sensor array.

### BACKGROUND OF THE INVENTION

The present invention relates to a three-dimensional sensor array suitable in particular for receiving electrical signals that occur in natural cell connections. The cell assemblies to be measured are, for example, tissue sections in the animal or human organism. In particular, the invention makes possible the recording of electrical or electromagnetic signals that are generated by neurons and are forwarded to surrounding neurons or to muscular cells. The sensor array in accordance with the invention is also used in the examination of cell cultures cultivated outside of an organism, for example, in a culture system.

In order to detect electrical signals occurring in biological tissue, two basically different solution approaches were pursued in the past. It has been possible for a long time to record a summation signal such as occurs on the surface of a biological tissue with areally applied electrodes, for example, on the surface of the skin of a patient when recording an EEG. The precise position of the production and forwarding of such signals inside the biological tissue cannot be examined with this method. The attempt has been recently made to examine more closely the signals produced in the biological tissue and the processes of biological ion conduction occurring there in that measuring electrodes are positioned at individual positions inside a three-dimensional tissue body in order to record the signals punctually. However, this has the problem that the precise production site of the signals and the path of their forwarding are not known so that the positioning of the electrodes is very difficult. The signal distribution in space can also not be determined with such probes. Furthermore, there is basically the problem in the detection of signals inside biological tissue that a corrosion of the electrodes and/or in the medium range a tissue change occurs on account of the electrochemical series that is being built up, as a result of which the detected signals are falsified. This problem is present if electrical signals are to be fed via the electrodes into the biological tissue for purposes of stimulation.

Sensors have been recently suggested that should mitigate the problem of the exact positioning of the electrodes inside the tissue. For example, the so-called Utah electrode array has been described which concerns a miniaturized sensor array that comprises numerous sensor needles on a carrier that each have an electrode on their sensor tip. In order to make possible the detection of signals in tissue layers at different depths (Z direction) the sensor needles can have http://www.medgadget.com/archives/print/002076print.html). different lengths so that when they penetrate into the tissue they penetrate into it with different depths (“Utah Electrode Array to Control Bionic Arm”; May 24, 2006;

However, even with this sensor array the spatial distribution of electrical signals in biological tissue can be detected only to a very limited extent because each sensor needle of the array detects signals only at a certain depth in the tissue. Furthermore, there is the problem, due to the construction of the sensor array, that an unhindered fluid flow through the array is hindered by the continuous carrier plate, as a result of which the supplying of cell cultures with nutrients in culture systems is significantly adversely affected.

A three-dimensional sensor array with sensor needles arranged in a comb-like manner and mutually spaced in the x and the y direction is known from JP 2004237077A. Each sensor needle has several electrode surfaces distributed in the longitudinal direction on the sensor needle.

US 2003/0100823 A1 shows a three-dimensional sensor array with several sensor needles arranged in a comb-like manner. Each sensor needle is provided with several electrode surfaces arranged distributed in the longitudinal direction on the sensor needle.

WO 2010/005479 A1 describes a three-dimensional sensor array for measuring electrical signals in biological cell assemblies. In the sensor array previously known from this publication each sensor needle has only one electrode surface.

### SUMMARY OF THE INVENTION

Thus, one task of the present invention consists in making available an improved three-dimensional sensor array with which electrical signals can be precisely detected in a three-dimensional biological cell combination, in particular as concerns the time and place of the occurrence of such signals. A partial task is seen in modifying a sensor array in such a manner that a currentless measuring in tissue structures becomes possible in order to prevent the corrosion of electrodes and tissue changes. Finally, another partial task consists in modifying the sensor array in such a manner that it is not only suitable for being used in the living organism but is also suitable in particular for the measuring of cell combinations cultivated in a bioreactor and does not adversely affect the supplying of the cultivated cells with nutrients.

The previously cited main task is solved by a three-dimensional sensor array in accordance with the attached claim 1. The cited partial tasks are solved in particular by preferred embodiments in accordance with the subclaims.

The sensor array in accordance with the invention is composed of several micro-structured sensor plates that each comprises a carrier section on which several sensor needles are arranged in a comb-like manner. The sensor needles are spaced from each other in a first direction (X direction) and carry several electrode surfaces distributed in the longitudinal direction of the sensor needles (Z direction). Each of the electrode surfaces is contacted via its own conducting track, whereby all conducting tracks run over the carrier section to a contacting section. Spacer elements are located between the several sensor plates which elements serve for the spacing of the sensor plates and preferably at the same time for the fastening of these plates. In this manner the carrier sections and the sensor needles formed on them are spaced from the adjacent sensor plates in a second direction (Y direction) that runs vertically to the first direction and to the longitudinal direction of the sensor needles (Z). Passages are formed between the spacer elements and the carrier sections which passages allow a fluid running through the sensor array to flow between the sensor plates in the longitudinal direction of the sensor needles.

Numerous electrode surfaces that are spatially arranged distributed in a grid are formed by the buildup of the sensor array in accordance with the invention. If the sensor array is introduced into a biological tissue, occurring electrical signals regarding the location can be precisely determined in the space in which the sensor needles extend. Since all electrode surfaces are individually contacted and therefore the particular signals detected can be forwarded to an evaluation unit, the signal amount being produced can be solved in time and in space so that the point of production as well as the types of the forwarding of signals in the tissue combination can be recorded.

The sensor needles in the sensor array can be manufactured as needle structures preferably consisting of silicon or vitreous silicon dioxide surfaces with a metallic core by known methods of nanotechnology. For example, self-organizing processes of etching, overgrowth and forming can be used. It is also possible to form surface structures on the sensor needles which structures facilitate an anchoring in biological tissue. Microstructural components with such formed, nanostructured surfaces are known, for example, from WO 2007/017458 A1, which is referred to regarding the production of such surface structures.

According to a preferred embodiment of the present invention the spacer elements extend exclusively between the carrier sections of the sensor plates, so that free spaces remain between the sensor needles of adjacent sensor plates which spaces can be filled by the biological tissue to be examined. A flow of liquid through the sensor array in the Z direction is made possible by the passages formed between spacer elements and the carrier sections. Thus, the sensor array can be designed in a very simple manner as a component of a culture system, whereby the supplying of nutrients to the individual tissue layers is not adversely affected or is even facilitated by the positioning of the sensor arrays.

The essential elevation of the sensitivity of the electrical measuring by the needle-like, grass-like nanostructures on the surface of the sensor needles is advantageous. At the same time, these nanostructures can be attached on the surface of the joint to the next sensor plate and thus contribute to the novel buildup and connection technique to the real 3-D-MEA in that they are pressed into the plastic maintaining the spacing. Such novel buildup and connection techniques used on materials that are additionally effective in a capacitive manner make possible the three-dimensionality of the described sensors.

An advantageous embodiment is distinguished in that the surface of the sensor needles is rendered biologically passive. The creation of electrochemical series can be prevented by applying appropriate coatings. The procedure for a biological passivation of semiconductor materials such as can be used for the manufacture of sensor needles is basically known to the person skilled in the art so that a detailed description will not be given. However, it is especially advantageous in this connection if even the electrode surfaces are coated with an electrically insulating, in particular biologically passivated covering. The signal detection takes place in this case by capacitive measuring methods, whereby the individual electrode surfaces form an electrode of a measuring capacitor. The required counterelectrode can be realized by opposing electrode surfaces on the sensor needles or also by a common capacitor plate, which represents an independent component of the sensor array. In order to reduce the cross talk during the signal detection the conducting tracks in the sensor array can be provided with an electromagnetically active screening.

The above-cited task is also solved in accordance with the invention by a measuring assembly in accordance with the coordinate claim 7. This measuring assembly comprises a previously described sensor array as well as an evaluation unit connected to it which evaluation unit detects and processes in time and as to location the signals delivered from the several electrode surfaces of the sensor array. The evaluation unit or parts of it can be constructed as an on-chip-signal processing circuit and be arranged in the direct vicinity of the electrode surfaces on the sensor array. As a result, a data reduction can be carried out on-chip so that a reduced amount of data can be transmitted, for example, by a wireless communication connection to an external data processing unit. Moreover, the measuring assembly can preferably comprise a signal generator that can supply an electrical stimulation signal to one or more electrode surfaces of the sensor array. Thus, not only the signals naturally produced in the biological tissue can be detected but a purposeful stimulation is also possible, for example, in order to activate muscle cells or to simulate other processes in the tissue combination.

### BRIEF DESCRIPTION OF THE DRAWINGS

Further advantages, details and further developments of the present invention result from the following description of preferred embodiments with reference made to the drawings. In the drawings:

FIG. 1 shows a simplified view of the sensor plate for several sensor needles in a top view;

FIG. 2 shows an arrangement of several sensor plates on a wafer during a manufacturing step;

FIG. 3 shows a perspective view of a spacer element;

FIG. 4 shows a perspective view of a first embodiment of a three-dimensional sensor array;

FIG. 5 shows an assembly drawing with modified embodiments of the components of the sensor array;

FIG. 6 shows a perspective view of a cell cultivation system with integrated sensor array.

### DETAILED DESCRIPTION

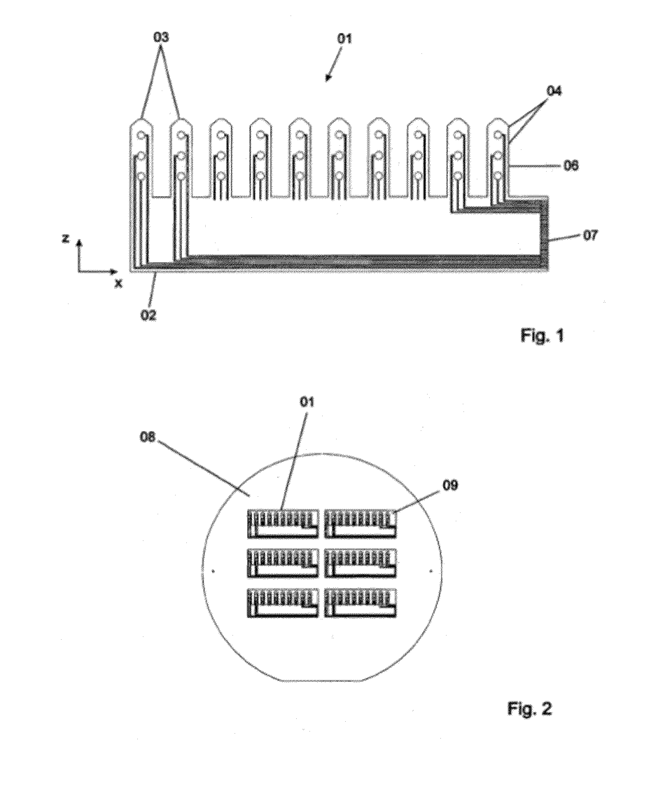

FIG. 1 shows a first component of the sensor array in accordance with the invention in a simplified top view. It concerns a sensor plate 01 that is manufactured by micro-structuring and comprises a carrier section 02 as well as numerous sensor needles 03. The sensor needles 03 are arranged in a comb-like manner on the carrier section 02 and spaced from each other in the X direction. The space between the individual sensor needles is, for example, 50 to 1000 μm. Several electrode surfaces 04 are arranged on each sensor needle 03 and are spaced from each other in the Z direction (longitudinal direction). Each electrode surface is connected to its own conducting track 06 so that numerous conducting tracks 06 run on the sensor plate that are guided via the carrier section 02 to a contacting section 07.

FIG. 2 shows the arrangement of several sensor plates 01 on a wafer 08 during a manufacturing step. In this phase of the manufacture the sensor needles 03 are at first still surrounded by a structuring area 09 that must later be removed, e.g., by etching or sandblasting in order to expose the comb-like structure of the sensor needles. The at first two-dimensional production of the structures on the individual sensor plates preferably takes place by standard MEMS technologies. For example, an insulating substrate (glass, Borofloat 33) in wafer form is used as starting material. Metallic layers are separated off with the aid of thin-layer technologies (sputtering, vaporization) which layers can subsequently be structured by lithography and etching. In order to keep low the influencing of the cell cultures to be examined later by the sensor array, an insulating, biocompatible passivation layer (preferably Si₃N₄ or SiO₂) is separated off over the entire structure with a low-temperature separating method (PECVD). The electrode surfaces 04 are subsequently exposed again by a further etching step in as far as a capacitive measuring is not preferred. Corresponding structuring steps can be carried out on both sides of the wafer disk in order to apply electrode surfaces on both sides of the sensor needles. Deviating manufacturing steps are necessary if the conducting tracks 06 are to be additionally provided with a screening.

After the electrode surfaces and the conducting tracks have been manufactured the comb structure for the individual sensor needles must be manufactured, for which a structuring through the complete wafer is required. Net- and dry chemical etching processes can be used for this. A micro-sandblasting is also possible when using pre-structured masks, which drastically reduces the working time. The sensor plates manufactured in this manner are subsequently singled so that several sensor plates are present.

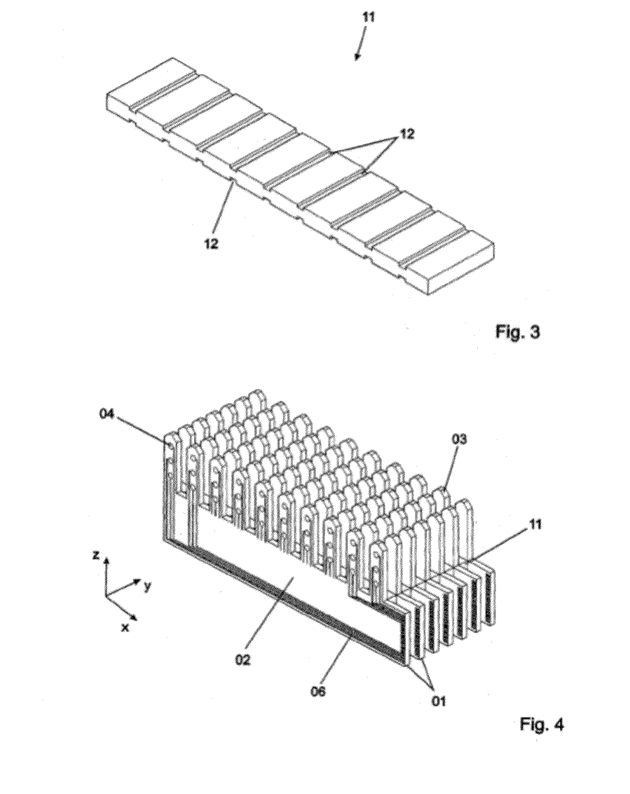

FIG. 3 shows a perspective view of a preferred embodiment of a spacer element 11 that forms another component of the sensor array of the invention. The spacer element 11 preferably consists of plastic, in particular polycarbonate. The spacer element corresponds in its dimensions as regards width and length approximately to the measurement of the carrier section 02 of the sensor plate. The thickness of the spacer element determines the later spacing of the individual sensor plates in the Y direction and is, for example, 50 to 1000 μm. Several passages 12 are formed as groove-shaped recesses in the spacer element 11, preferably on both sides. In the assembled sensor array these passages 12 bring it about that a fluid current, for example, a nutrient solution, can flow through and is thus maintained between the individual sensor plates.

FIG. 4 shows a perspective view of a first embodiment of the sensor array. The latter obviously consists of several sensor plates 01 that are spaced from each other by intermediate spacer elements 11 in the Y direction so that numerous sensor needles 03 are arranged in a matrix fashion. The electrode surfaces 04 attached on the sensor needles 03 are distributed over the space defined by the sensor needles. The hybrid three-dimensional buildup of the sensor array preferably takes place by thermal compression bonding. To this end the spacer elements 11 are alternatingly stacked with the sensor plates 01, heated in a thermal press to approximately 90% of the softening temperature of the material of the spacer elements and loaded with a pressure of, for example, 5 MPa. The surfaces of the spacer elements and of the sensor plates standing in contact can be previously pre-treated by a plasma activation. The required thermal bond time is approximately 3 min.

If the spacer elements do not consist of plastic but rather of silicon in alternative embodiments the connection between the spacer elements and the sensor plates can be produced by anodic bonding. In this case the stack of spacer elements and sensor plates must be sequentially bonded.

It is apparent that as a result of the buildup in accordance with the invention sufficient space remains between the sensor needles 03 so that biological cells can settle there. The sensor array can be introduced into natural cell surroundings in that the sensor needles are pushed into the tissue. In distinction to other matrix-like sensor arrays a flow of fluid even in the Z direction remains possible since, in spite of the required shunting of the numerous conducting tracks on the carrier sections between the individual sensor plates, flow conduits are formed with the aid of the passages 12. Such a flowing through is required in particular in the cultivation of biological cells in order to supply sufficient nutrient solution to all cells in a three-dimensional combination.

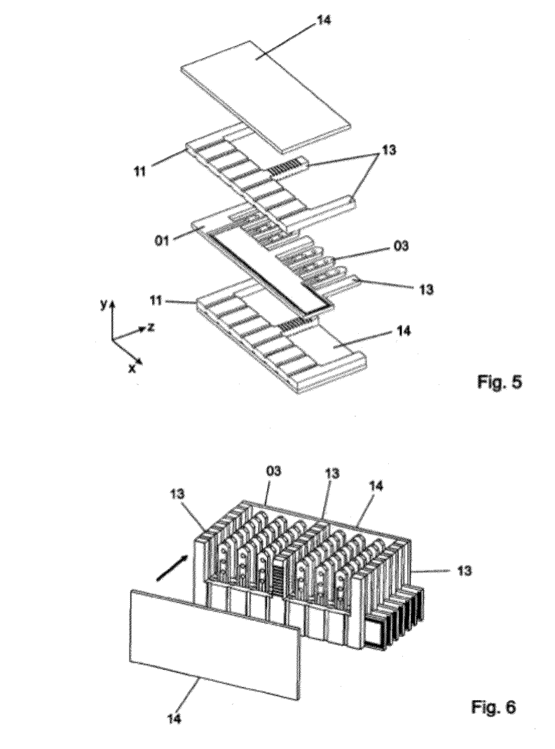

FIG. 5 shows a modified embodiment of the components of the sensor array in an assembly drawing. The sensor plates 01 as well as the spacer elements 11 have in this embodiment separating webs 13 that have approximately the length of the sensor needles 03 in the Z direction. In the X direction the separating webs 13 are uniformly positioned so that they lie tightly on the particular separating webs of the adjacent plates (sensor plate and spacer element) after the assembly of the plate stack. Furthermore, additional covering plates 14 are provided on the edges of the plate stack that enclose the space of the intermediate sensor needles.

FIG. 6 shows a perspective view of the largely assembled state of a modified embodiment of the sensor array, that in this case is an integral component of a cell cultivation system. A cultivation space is created by the outer separating webs 13 as well as by the cover plates 14 in which space several sensor needles 03 are arranged, whereby a cell culture can be cultivated between the latter. In the embodiment shown the cultivation space is divided into two chambers separated by central separating webs 13. A communication can take place between the two chambers via conduits provided in the central separating webs so that fluids can flow and/or a cell emigration can take place. For example, neurons can be cultivated in one chamber while muscle cells grow in the other chamber. Axons of the neurons can grow through the conduits in the central separating webs and dock on the muscle cells. The signals being produced and their propagation can be determined in a resolved manner locally and in time in both chambers with the aid of the sensor array.

1. A three-dimensional sensor array for measuring electrical signals and biological cell assemblies, comprising:
several micro-structured sensor plates (1) each with a carrier section (2) on which several sensor needles (3) are arranged in a comb-like manner so that they are spaced from each other in a first direction (X), whereby each sensor needle (3) comprises several electrode surfaces (4) distributed in the longitudinal direction (Z) on the sensor needle (3) which electrode surfaces are contacted on their own conducting track (6), and whereby the conducting tracks (6) run via the carrier section (2) to a contacting section (7);
several spacing elements (11) fastened between the sensor plates (1) so that the carrier sections (2) as well as the sensor needles (3) of adjacent sensor plates (1) are spaced from each other in a second direction (Y), whereby passages (12) are formed between the spacer elements (11) and the carrier sections (2) which passages allow a flow of fluid that runs through the sensor array between the sensor plates (1) in the longitudinal direction (Z) of the sensor needles (3).

2. The sensor array according to claim 1, characterized in that the spacer elements (11) extend exclusively between the carrier sections (2) of the sensor plates (1) and leave free spaces between the sensor needles (3).

3. The sensor array according to claim 1, characterized in that the surface of the sensor needles (3) is biologically passivated.

4. The sensor array according to claim 1, characterized in that the electrode surfaces (4) are coated with an electrically insulating, biologically passivated covering.

5. The sensor array according to claim 1, characterized in that the conducting tracks (6) are provided with an electromagnetically active screening.

6. The sensor array according to claim 1, characterized in that the sensor needles (3) comprise barbed nanostructures on their surfaces.

7. A measuring assembly for measuring electrical activities of biological cell assemblies, characterized in that it comprises a sensor array according to claim 1 that is connected to an evaluation unit that detects and processes in time and as to location in a resolved manner the signals delivered from the several electrode surfaces (4) of the sensor array.

8. The measuring assembly according to claim 7, characterized in that the evaluation unit detects and evaluates capacitance changes on the electrode surfaces (4), whereby the individual electrode surfaces (4) form an electrode of a measuring capacitor, whereby the counterelectrode of the measuring capacitor is formed by an opposite electrode surface (4) on a sensor needle (2) or by a common capacitor plate.

9. The measuring assembly according to claim 7, characterized in that it comprises a signal generator that supplies an electrical stimulation signal to one or more of the electrode surfaces (4) when activated.

10. The sensor array according to claim 2, characterized in that the surface of the sensor needles (3) is biologically passivated.

11. The sensor array according to claim 2, characterized in that the electrode surfaces (4) are coated with an electrically insulating, biologically passivated covering.

12. The sensor array according to claim 3, characterized in that the electrode surfaces (4) are coated with an electrically insulating, biologically passivated covering.

13. The sensor array according to one of claim 2, characterized in that the conducting tracks (6) are provided with an electromagnetically active screening.

14. The sensor array according to claim 3, characterized in that the conducting tracks (6) are provided with an electromagnetically active screening.

15. The sensor array according to claim 4, characterized in that the conducting tracks (6) are provided with an electromagnetically active screening.

16. The sensor array according to claim 2, characterized in that the sensor needles (3) comprise barbed nanostructures on their surfaces.

17. The sensor array according to claim 3, characterized in that the sensor needles (3) comprise barbed nanostructures on their surfaces.

18. The sensor array according to claim 4, characterized in that the sensor needles (3) comprise barbed nanostructures on their surfaces.

19. The sensor array according to claim 5, characterized in that the sensor needles (3) comprise barbed nanostructures on their surfaces.

20. The measuring assembly according to claim 8, characterized in that it comprises a signal generator that supplies an electrical stimulation signal to one or more of the electrode surfaces (4) when activated.
